(19) United States
(12) Patent Application Publication
(10) Pub. No.: US 2026/0339403 A1
(43) Pub. Date: Oct. 29, 2026

(54) DISTRIBUTED COOLING FOR ENHANCED SYSTEM MANAGEMENT

(71) Applicant: Dell Products L.P., Round Rock, TX (US)

(72) Inventors: WUCK FOO WONG, Upton, MA (US); WEIDONG ZUO, Shrewsbury, MA (US); JAMES R. UTZ, Georgetown, TX (US)

(21) Appl. No.: 19/192,512

(22) Filed: Apr. 29, 2025

(51) Int. Cl. G06F 1/20; H05K 7/20

(52) U.S. Cl. CPC G06F 1/206; H05K 7/20263; H05K 7/20281; H05K 7/20636; H05K 7/207

(57) ABSTRACT

Methods, systems, and devices are provided for thermally managing a data processing system. To do so, a first portion of cooling components in a chassis of the data processing system, and a second portion of cooling components positioned with a cooling module separate from the chassis, may be identified. Using the first portion and the second portion, a thermal management algorithm for thermally managing hardware resources of the data processing system may be selected. Using the selected algorithm, first operating points for the first portion, and second operating points for the second portion, may be selected. The second operating points may thereby be set for the second portion using a hybrid power and data channel between the management component and the second portion to modify a cooling rate for the hardware resources to retain the hardware resources within thermal operating limits.

### FIELD

Embodiments disclosed herein relate (generally) to thermal management of data processing systems. More particularly, embodiments disclosed herein relate to systems and methods for mitigating (e.g., heat) damage to data processing systems.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components and the components of other devices may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1A-1B show diagrams illustrating a data processing system in accordance with an embodiment.

FIGS. 1C-1D show diagrams illustrating a hybrid power/data channel in accordance with an embodiment.

FIG. 2 shows an interaction diagram illustrating processes and interactions in accordance with an embodiment.

FIG. 3 shows a flow diagram illustrating a method in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary de vices, such as in a network topology.

In general, embodiments disclosed herein relate to methods and systems for managing a data processing system. The data processing system may provide computer-implemented services. To do so, operation of hardware components may facilitate various functionalities of the data processing system, a byproduct of such operation resulting in a generation of heat.

If the generated heat is not properly regulated (e.g., dissipated), the hardware components may be damaged due to a buildup of the generated heat that is beyond the thermal range (e.g., beyond thermal operating limits) for optimal operation of the data processing system.

Consequently, damage to the hardware components may cause workloads performed by the hardware components and/or facilitated functionalities of the data processing system to be lost (referred to as “workload loss”) and/or otherwise deprecated (resulting in less-than-optimal operation of the data processing system at best). Such loss and/or deprecation may, in turn, negatively impact (e.g., delay and/or prevent entirely) the data processing system's providing of the computer-implemented services.

To increase the likelihood of placing the data processing system in the operable conditions (therefore increasing a likelihood of the computer implemented services being provided as expected and/or desired by a consumer of such services), the data processing system may use various thermal components for distributed cooling. For example, such distributed cooling functionality of the data processing system may include, and/or accommodate the installation of, a first portion of cooling components housed in a chassis of the data processing system that may house the above-mentioned hardware components, and/or a second portion of cooling components that may be a part of a (separate) cooling module that may, for example, be housed separately from the above-mentioned hardware components. This first portion of cooling components and/or this second portion of cooling components may facilitate any combination of liquid and/or air-based cooling (e.g., heat transport/dissipation) for the hardware components.

By using such a combination of liquid and air heat transport/dissipation as the above-mentioned various thermal components, a data processing system (e.g., or more specifically, a management component of the data processing system) may (i) identify the various thermal components, for example, while differentiating between the first portion of cooling components and the second portion of cooling components, (ii) select a thermal management algorithm for thermally managing hardware resources (e.g., the hardware components housed in the chassis) of the data processing system, (iii) select first operating points for the first portion of cooling components and second operating points for the second portion of cooling components, (iv) set the first operating points for the first portion of cooling components and the second operating points for the second portion of cooling components to modify a cooling rate for any of the hardware components (“hardware resources”) to retain hardware component operating conditions within thermal operating limits, and/or (v) any other processes for retaining hardware component operations within the thermal operating limits may be performed, not to be limited by embodiments discussed herein.

Thus, such thermal operating limits may be retained, thereby increasing the likelihood of the computer-implemented services being provided by the data processing system as expected and/or desired by a consumer of such services.

In an embodiment, a method for thermally managing a data processing system is provided.

The method may include identifying, by a management component of the data processing system, a first portion of cooling components that are in a chassis of the data processing system and a second portion of cooling components that are position in a separate cooling module and operably connected to the management component; selecting, by the management component, a thermal management algorithm for thermally managing hardware resources of the data processing system using the first portion of the cooling components and the second portion of the cooling components; selecting, by the management component and using the thermal management algorithm and at least a temperature of one of the hardware resources, first operating points for the first portion and second operating points for the second portion; and setting, by the management component, the second operating points for the second portion using a hybrid power and data channel between the management component and the second portion of the cooling components to modify a cooling rate for at least the one of the hardware resources to retain the one of the hardware resources within thermal operating limits.

The hybrid power and data channel may include a break-out circuit card positioned with a pass-through at a first end of the chassis; a connection between the break-out circuit card and the management component and/or main circuit board; and a hybrid power/data cable to interconnect the break-out circuit card with the second portion of the cooling components.

The connection may be adapted to retrieve power from the main circuit board, and the break-out circuit card may be adapted to direct the power to the second portion of the cooling components via the hybrid power/data cable.

The break-out circuit card may be adapted to be positioned in a peripheral component interface express (PCIe) slot in the chassis.

The pass-through may include openings for a pair of fluid lines to pass through to establish a cooling loop from the one of the hardware resources to the second portion of the cooling components.

The second portion of the cooling components may include a fan; a pump to pump a cooling liquid; and a thermal dissipator to cool the cooling liquid using an airflow generated by the fan.

The separate cooling module may be unable to power itself and may rely on the data processing system to power, at least, the fan and the pump.

The separate cooling module may be unable to set operating points of at least the fan and the pump and may rely on the data processing system to set the operating points of the at least the fan and the pump.

The second portion of the cooling components may be adapted to provide cooling for the one of the hardware resources and at least one other hardware resource positioned in a second data processing system; and the data processing system, the separate cooling module, and the second data processing system being positioned in a rack.

The management component may be a management controller that is hosted by the data processing system but operates independently from the hardware resources, the management controller being tasked with managing operation of the hardware resources while the hardware resources provide desired computer implemented services.

A non-transitory media may include instructions that when executed by a processor cause the computer-implemented method to be performed.

A system may include the non-transitory media and a processor and may perform the computer-implemented method when the computer instructions are executed by the processor.

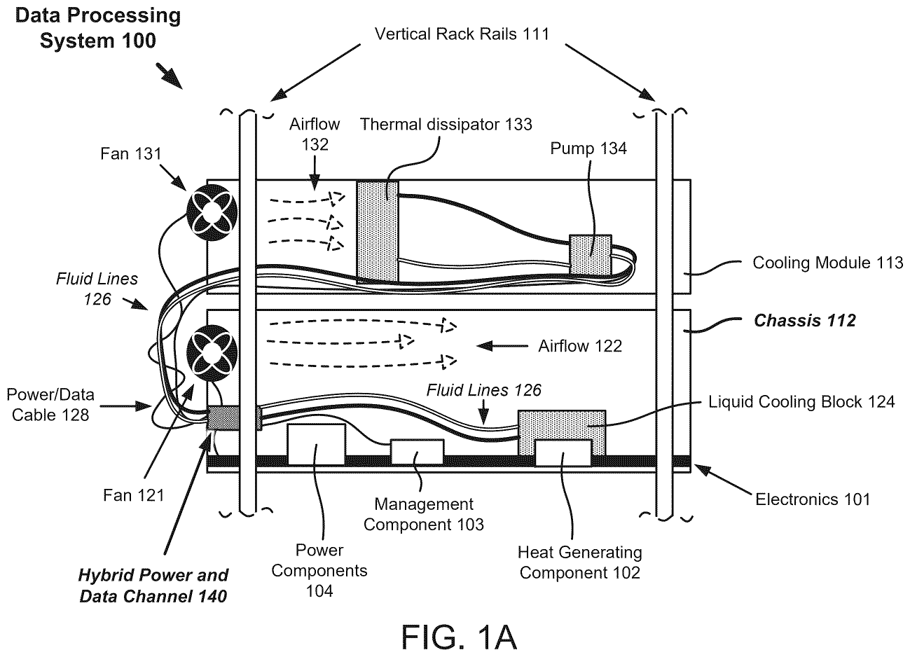

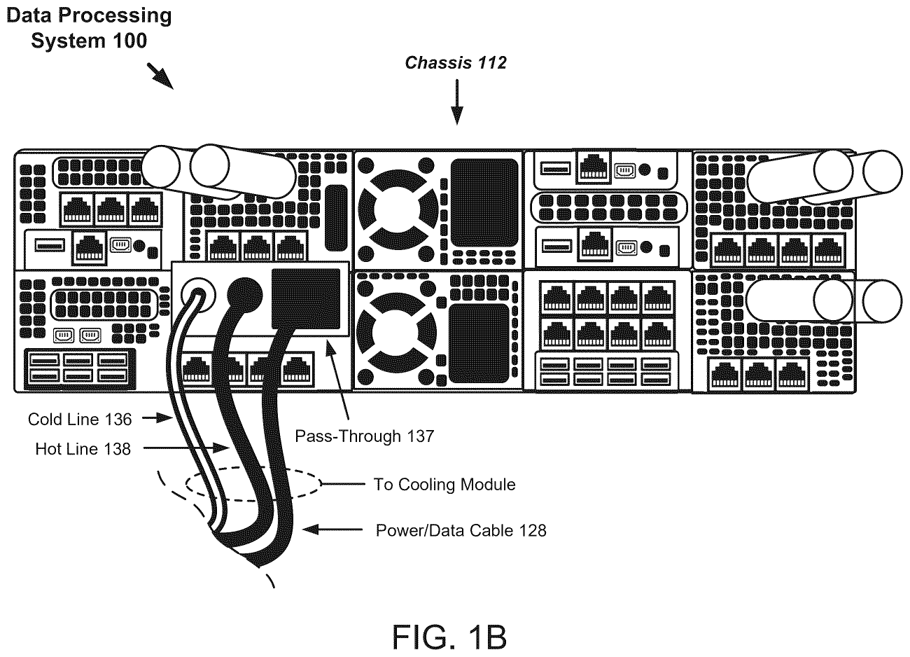

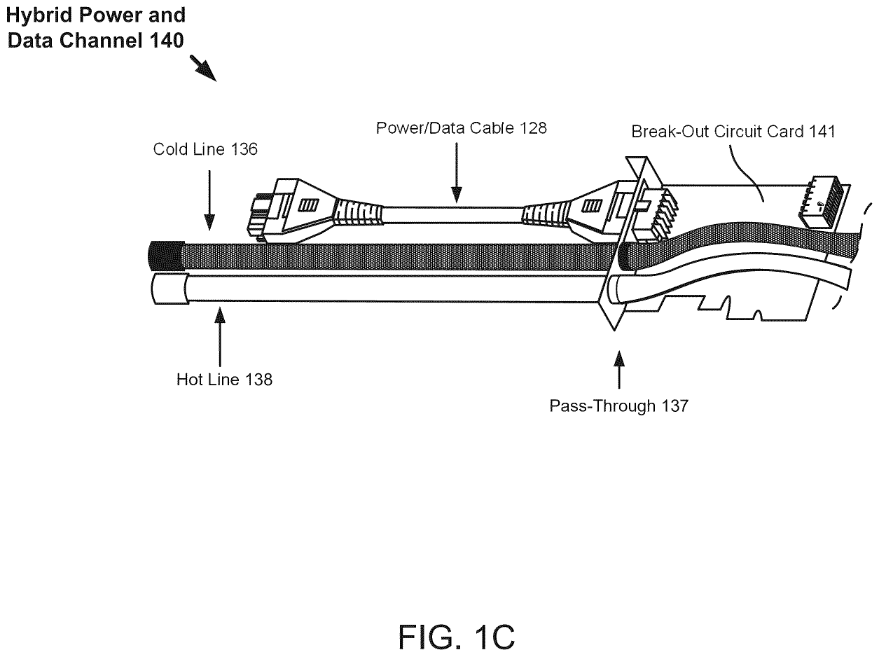

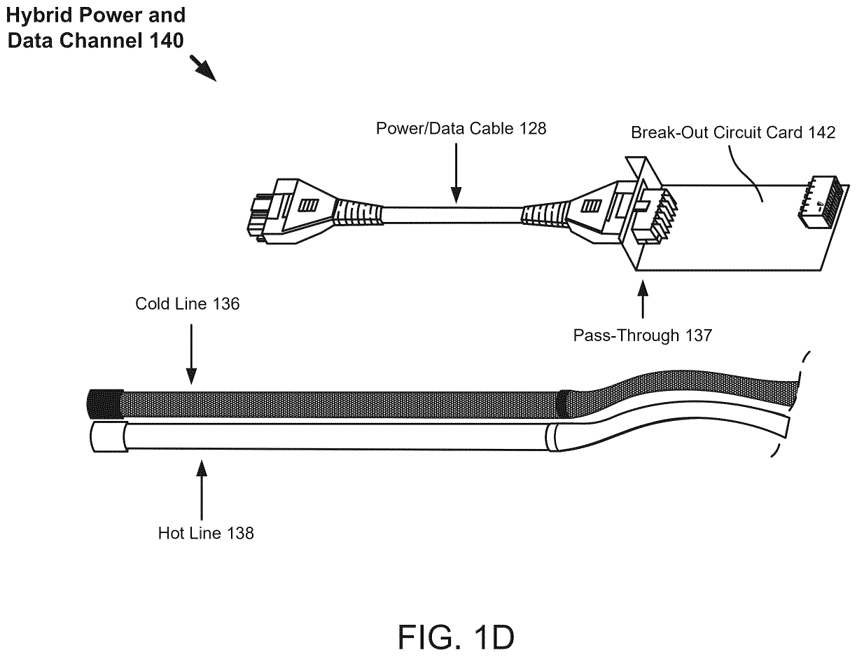

Turning to FIG. 1A, a first diagram illustrating a data processing system (e.g., 100) in accordance with an embodiment is shown. The viewpoint may include a side view of the data processing system, a rear of the data processing system (e.g., a rear of chassis 112) facing a left of the page, and a front of the data processing system (e.g., a front of chassis 112) facing a right of the page. The data processing system shown in FIG. 1A may provide computer implemented services, as discussed below.

The computer implemented services may include any type and quantity of computer implemented services. The computer implemented services may include, for example, database services, data processing services, electronic communication services, and/or any other services that may be provided using one or more computing devices. The computer implemented services may be provided by, for example, any portion of data processing system 100, and/or any other type of devices not to be limited by embodiments discussed herein.

Other types of computer implemented services may be provided by the system shown in FIG. 1A without departing from embodiments disclosed herein.

To provide the computer implemented services, data processing systems may include any number of hardware components. For example, operation of the any number of hardware components may facilitate various functionalities of a data processing system, thereby causing the data processing system to provide the computer implemented services. For example, to facilitate the various functionalities, a hardware component may transmit data to and/or from other devices via various avenues of communication. For example, such avenues of communication may depend on physical operable connections that directly connect multiple hardware components to one another.

To provide its functionality of providing computer implemented services, the data processing system may be implemented by data processing system 100, as shown in FIG. 1A. Data processing system 100 may include, at least, for example, electronics 101, power components 104, chassis 112, and/or other types of components not to be limited by embodiments discussed herein. Each of these is discussed below.

Electronics 101 may provide hardware resources that may be operably connected with one another for facilitating data processing system 100's functionality (e.g., via their own respective operations). Such hardware resources may include any number of the hardware components, and may, as previously mentioned, cause the providing of the above-mentioned computer implemented services. It will be appreciated that in some contexts, at least a portion of the hardware components may be referred to instead as hardware resources of data processing system 100.

To provide their functionality, electronics 101 may be implemented by electrical (e.g., computing) devices positioned on circuit cards (e.g., depicted with solid black in-fill in FIG. 1A). For example, Electronics 101 may include electrical (e.g., computing) devices (e.g., as shown in FIG. 1A) such as heat generating component 102 and management component 103. Each of these is discussed below.

Heat generating component 102 may be positioned within a chassis of data processing system 100 and may consume power to operate, the operation depending on a capability to receive power (e.g., at least a minimum quantity of power required to operate in an expected and/or desired manner). This operation may, for example, (i) facilitate at least a portion of data processing system 100's functionalities, and (ii) generate heat as a byproduct. For example, heat generating component 102 may be a computing device operably connected to the rest of electronics 101 via cabling, circuitry, and/or other types of operable connections along which electrical signals may traverse.

To provide its functionality, heat generating component 102 may, for example, be implemented by a processor of data processing system 100 (e.g., a central processing unit (CPU) and/or a graphics processing unit (GPU) of data processing system 100) adapted to perform at least a portion of a workload queued for performance by data processing system 100.

For additional information regarding the heat produced as a byproduct of the operation, continue further below through the following/remaining discussions of FIGS. 1A-1D.

Management component 103 may (i) operate independently from hardware resources of data processing system 100, (ii) be distinct from the hardware resources, and (iii) be adapted to manage the hardware resources.

To provide its functionality, management component 103 may be implemented by, for example, a management controller that is hosted by data processing system 100, but that operates independently from the hardware resources, management component 103 being tasked with managing operation of the hardware resources while the hardware resources facilitate the providing of the computer implemented services.

To do so, for example, management component 103 may be adapted to (i) consume power independently from the rest of data processing system 100, and (ii) communicate with each one of the hardware resources via respective out-of-band communication channels, each of these channels being used to establish one-to-one-communication likely to be untampered with for each one of the hardware resources. Therefore, transmission of data via these out-of-band communication channels and supported functionality for power consumption independent from the rest of the system's power consumption may decrease a likelihood of unpredictable and/or undesirable impacts on data processing system 100's operation. By using such out-of-band communications, manipulation by, and/or influence that may be otherwise from, a vulnerability (that may have been compromised) of data processing system 100 may be circumvented to continue facilitating system management with a decreased likelihood of negatively impacting services to be provided by data processing system 100.

For additional information regarding how management component 103 may manage the hardware resources, refer to the discussions of FIG. 1A that follow below and/or refer to the discussions of FIGS. 1B-3, further below.

Power components 104 may power the hardware resources (hardware components) of data processing system 100 (e.g., electronics 101) as well as, for example, any portions of data processing system 100 not housed by chassis 112 (e.g., cooling module 113, discussed further below).

To provide its functionality, (in some cases) for example, power components 104 may be implemented using power supplies. In some other cases, for example, power components 104 may be implemented using power rails and/or other types of operable connections that receive/distribute power provided by a busbar that distributes power throughout, for example, a rack system (e.g., at least partially depicted using vertical rack rails 111 on which chassis 112 may be vertically stacked with other enclosures in the rack (e.g., cooling module 113). Such power may be provided to the busbar by power supplies, for example.

Electronics 101, power components 104, and/or other components of data processing system 100 (not to be limited by embodiments discussed herein) may be positioned in chassis 112 such that chassis 112 may be adapted to house said components within chassis 112's interior.

By being adapted to house various components, chassis 112 may be further adapted to facilitate placement/positioning of a limited number of the components, the limited number of components being due to limited available cubic space (e.g., limited interior volume of the chassis) as well as a limited quantity of port slots (e.g., connection interfaces) with which operable connection may be established between data processing system 100 and a component whose connection interface makes complete, physical contact with at least one of the port slots in chassis 112.

To provide its functionality, chassis 112 may be implemented by an enclosure in which at least a portion of physical structures of electronics 101 (e.g., processors, memory, etc.), and/or other components of data processing system 100 may be positioned. For example, chassis 112 may facilitate placement and management of electronics 101 and/or the other components (e.g., power components 104 and/or at least a first portion of cooling components (previously mentioned) in computing environments such as those discussed herein, chassis 112 being implemented by, for example, a rack mount frame of a rack mount chassis system depicted with vertical rack rails 111.

Therefore, by housing various components whose operations may facilitate the various functionalities of data processing system 100 within the limited interior volume of chassis 112 while chassis 112 is mounted on vertical rack rails 111, hardware components of data processing system 100 may be positioned with the rack and with regard to one another. In such positioning, operable connections between data processing system 100 and the components may be facilitated by physical contact between component connection interfaces and port slots.

As previously mentioned, however, these hardware components may generate heat as a byproduct of their operation. Consequently, if such heat is not properly regulated (e.g., dissipated) to have data processing system 100 remain within an operational threshold (e.g., the range of thermal operating limits in which data processing system 100 is known to operate as expected and/or otherwise desired), the computer implemented services may be negatively impacted (e.g., may be delayed and/or prevented entirely). For example, excessive heat may physically damage the hardware components if respective thermal dissipation requirements of the hardware components are not met.

To improve the likelihood of providing the computer implemented services as expected and/or desired by a consumer of such services, a combination of liquid and/or air heat transport/dissipation (e.g., liquid/air-based cooling) may be utilized. For example, data processing system 100 may include a first portion of cooling components to facilitate thermal management for the hardware components.

This first portion of cooling components may include, for example, fan 121, liquid cooling block 124, and fluid lines 126, each of which is discussed below, and as shown in FIG. 1A, the first portion of cooling components may each be housed in chassis 112.

As previously discussed, chassis 112 may house, for example, heat generating component 102, and as its name suggests, heat generating component 102 may generate heat as a byproduct of its operation. In an attempt to dissipate this generation of heat, liquid cooling block 124 may be adapted for placement/installation within chassis 112 that is proximate to and/or secured too (e.g., on top of) heat generating component 102.

Liquid cooling block 124 may facilitate a dissipation of heat generated by, for example, heat generating component 102 by facilitating circulation of the cooling liquid through, for example, fluid lines 126 throughout the flow path of the cooling liquid.

To do so, liquid cooling block 124 may operate in a similar manner as that of a heat sink and a liquid cooling pump. For example, such operation of liquid cooling block 124 may require that liquid cooling block 124 be placed with heat generating component 102. By positioning liquid cooling block 124 with heat generating component 102, liquid cooling block 124 may facilitate, for example, (i) a traversal of the cooling liquid being pumped, such that the cooling liquid may traverse proximate to heat generating component 102 during heat generating component 102's operation, (ii) a receiving of at least a portion of the heat generated by heat generating component 102 (e.g., via a heat sink-like structure of liquid cooling block 124), (iii) a dissipation of the at least a portion of the heat received into the cooling liquid as the cooling liquid is circulated through liquid cooling block 124 while proximate to heat generating component 102, and (iv) a dispense of the cooling liquid from liquid cooling block 124, such that the cooling liquid may traverse away from the heat generating component 102 during heat generating component 102's operation. Thus, a transference of the at least a portion of the heat may be dissipated away from heat generating component 102.

To provide its functionality, liquid cooling block 124 may be implemented by, for example, a block-like component that includes a metal base made of a heat conducting material such as copper or aluminum, the metal base being adapted to sit on heat generating component 102 and allowing the at least a portion of the heat generated to be absorbed into the conducting material. In addition to the metal base, the block-like component make include an interior, or be positioned with some fluid lines such that proximate traversal of the cooling liquid may result in the heat absorbed into the metal base to be further absorbed into the cooling liquid (e.g., the fluid lines being positioned within this interior and/or otherwise positioned proximate to the metal base.

To direct the cooling liquid away from heat generating component 102, for example, chassis 112 may at least partially house fluid lines 126 within its interior as shown in FIG. 1A. Fluid lines 126 may include two types of fluid lines, a cold line and a hot line (not explicitly labeled in FIG. 1A). For example, assume the now warmed cooling liquid is directed toward a rear of chassis 112 via the hot line. In some cases, for example, this warmed cooling liquid may be received by a hollow manifold that carries the warmed cooled liquid away from the rack. Alternatively, another manifold similar to the first may, in some cases, direct a source of the cooling liquid from another hollow manifold that provides cooled cooling liquid into the cold line to flow back towards liquid cooling block 124, thereby resembling somewhat of a liquid cooling loop, each warming of the cooling liquid and directing of its flow to go away from heat generating component 102 being a first example mechanism of heat dissipation (this first example being liquid-based.

To provide its functionality, fluid lines 126 may be implemented by hollow, plastic tubes adapted to direct cooling liquid through the cooling loop for which it is a part, these tubes further directing the cooling liquid to cooling module 113 discussed further below.

For additional information regarding a fluid path of the cooling liquid illustrated in the system of FIG. 1A, refer to discussions regarding cooling module 113 further below.

While liquid cooling block 124 and fluid lines 126 contribute to cooling for data processing system 100 with liquid-based heat dissipation, other cooling components from the first portion may include air-based heat dissipation. Such an air-based form of heat dissipation may be facilitated by, for example, fan 121.

Fan 121 may direct an airflow (e.g., 122) through chassis 112's interior to provide air-based heat dissipation generally to a broad range of the hardware resources housed within the interior. To provide its functionality, fan 121 may be implemented by a standard chassis fan adapted to securely attach to walls of chassis 112. For example, fan 121 may be placed on a rear of chassis 112 as shown in FIG. 1A.

While both liquid-based and air-based heat dissipation is discussed with regard to the first portion of cooling components, it will be appreciated that, in some cases, hardware resources such as heat generating component 102 may generate heat at a rate that is too fast for the cooling liquid to dissipate the heat effectively, thereby allowing a buildup of heat being experienced by heat generating component 102 that may then increase the internal ambient temperature of chassis 112's interior. Additionally, as previously discussed, chassis 112 may have limited interior space and/or a limited number of port slots for operable connections.

For example, assume that chassis 112 may already be encumbered by hardware components housed within its interior. Consequently, fan 121 may be unable to provide sufficient supplemental cooling for heat generating component 102 and liquid cooling block 124 due to an inability/difficulty for airflow 122 to reach proximate enough to heat generating component 102.

Therefore, additional cooling may be necessary to provide adequate thermal management for data processing system 100. However, with chassis 112 encumbered (as the previously appreciated example assumption), and assuming, for example, that no port slots with adequate space proximate to themselves that would allow new operable connections for components is available for are available.

Therefore, to enhance thermal management of data processing system 100 to improve the likelihood of providing the computer implemented services as expected and/or desired by a consumer of such services, additional liquid and/or air heat transport/dissipation (e.g., liquid/air-based cooling) may be, for example, positioned with data processing system 100 using vertical rack rails 111 such that a second portion of cooling components may be operably connected with data processing system 100 while housed in a separate enclosure similar to chassis 112 (e.g., cooling module 113, thereby facilitating distributed cooling).

For example, to be provided additional liquid and/or air heat transport/dissipation, data processing system 100 may use (e.g., include) (i) hybrid power and data channel 140, and (ii) a second portion of cooling components housed in cooling module 113 (this second portion thereby being housed separately from components positioned within chassis 112's interior).

Hybrid power and data channel 140 may enable functionalities of the second portion of cooling components so they may be usable by management component 103.

Such functionalities may require enablement for use by data processing system 100 in this way due to the separate cooling module (e.g., 113) being unable to (i) power itself, thereby relying on data processing system 100 to power, at least, for example, fan 131 and pump 134, and (ii) set operating points of at least, for example, fan 131 and pump 134, thereby relying on data processing system 100 to set the operating points of at least fan 131 and pump 134.

Therefore, to provide its functionality, hybrid power and data channel 140 may include, for example, (i) power/data cable 128, (ii) fluid lines 126, (iii) break-out circuit cards, and/or (iv) a pass-through, each of which is discussed below with regard to FIGS. 1B-1D.

The second portion of cooling components housed in cooling module 113 may include (i) pump 134, (ii) thermal dissipator 133, and (iii) fan 131, each of which is discussed below.

Pump 134 may determine a rate of flow of the cooling liquid as the cooling liquid traverses along, and as directed by, fluid lines 126. For example, pump 134 may receive instructions to set an operating point with which when set may allow the rate of flow to be managed using the new operating point. As the rate of flow may be managed, the cooling liquid may be directed via fluid lines 126 to thermal dissipator 133, discussed below.

Thermal dissipator 133 may (i) receive a warmed cooling liquid once the cooling liquid is warmed due the dissipation of heat from passing through liquid cooling block 124, (ii) direct the warmed cooling liquid along its interior, flowing the warmed cooling liquid generally from a first side of thermal dissipator 133 to a second side of thermal dissipator 133, all the while airflow 132 traversing proximate to the surface area of thermal dissipator 133 resulting in the warmed cooling liquid to be re-cooled to obtain a re-cooled cooling liquid once reaching the second side of thermal dissipator 133, and (iii) dispensing of the re-cooled cooling liquid to provide the re-cooled cooling liquid back through pump 134, where from pump 134 the cooling liquid may follow its flow path through fluid lines 126 and back into the interior of chassis 112.

To provide its functionality, thermal dissipator 133 may be implemented by, for example, a radiator positioned within the enclosure that is the separate cooling module (e.g., 113) interior and positioned to be in thermal communication with at least a portion of the cooling components. For example, airflow 132 caused by fan 131 blowing air through cooling module 113's interior may assist in the dissipation of heat absorbed to the radiators surface area from the warmed cooling liquid, enough of the dissipation resulting in the re-cooling of the warmed cooling liquid to obtain the re-cooled cooling liquid.

For additional information regarding the above-mentioned hybrid channel (e.g., 140), refer to FIGS. 1B-1D discussed further below.

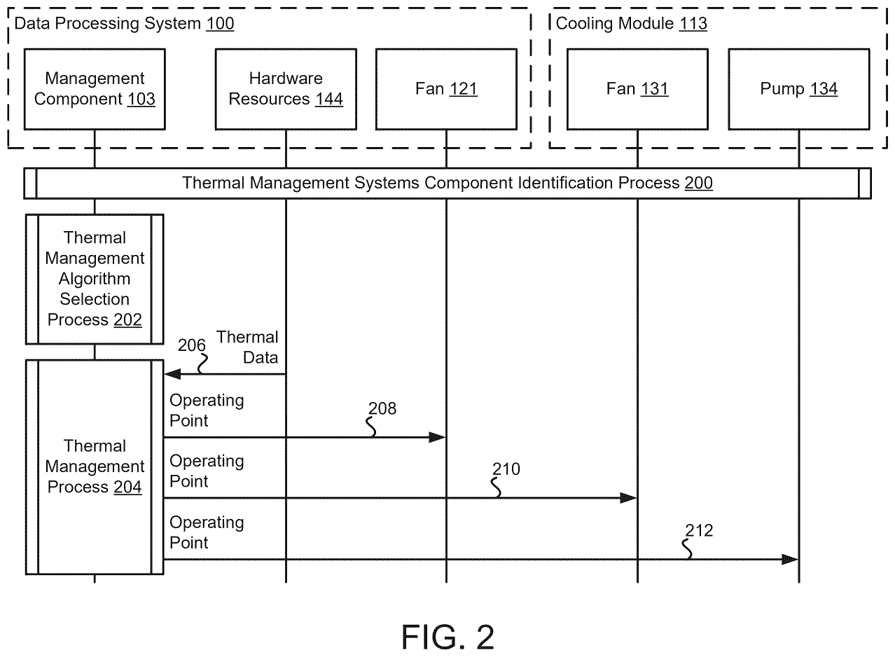

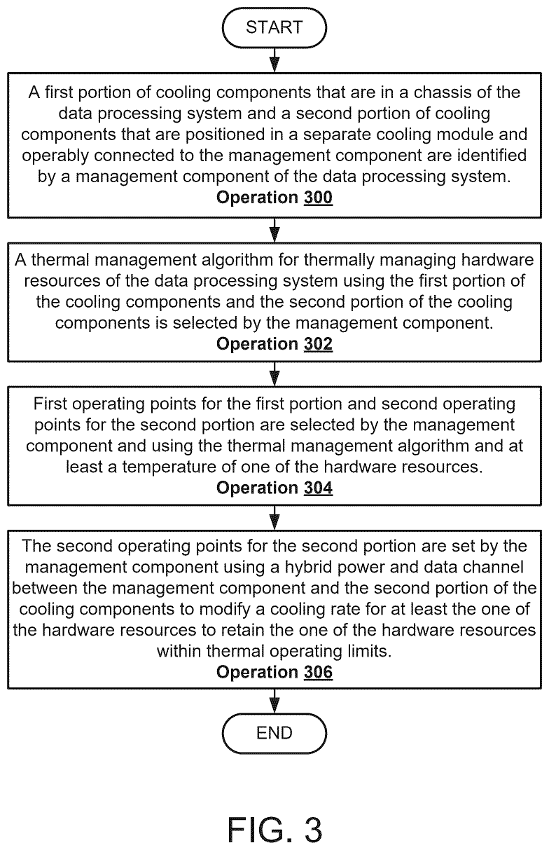

While providing their functionality, any portion of data processing system 100 (e.g., and/or any component thereof) may provide all or a portion of the methods shown and discussed with regard to FIGS. 2-3.

Data processing system 100 (e.g., and/or any components thereof) may be implemented using a computing device (also referred to as a data processing system) such as a host or a server, a personal computer (e.g., desktops, laptops, and tablets), a “thin” client, a personal digital assistant (PDA), a Web enabled appliance, a mobile phone (e.g., Smartphone), an embedded system, local controllers, an edge node, and/or any other type of data processing device or system.

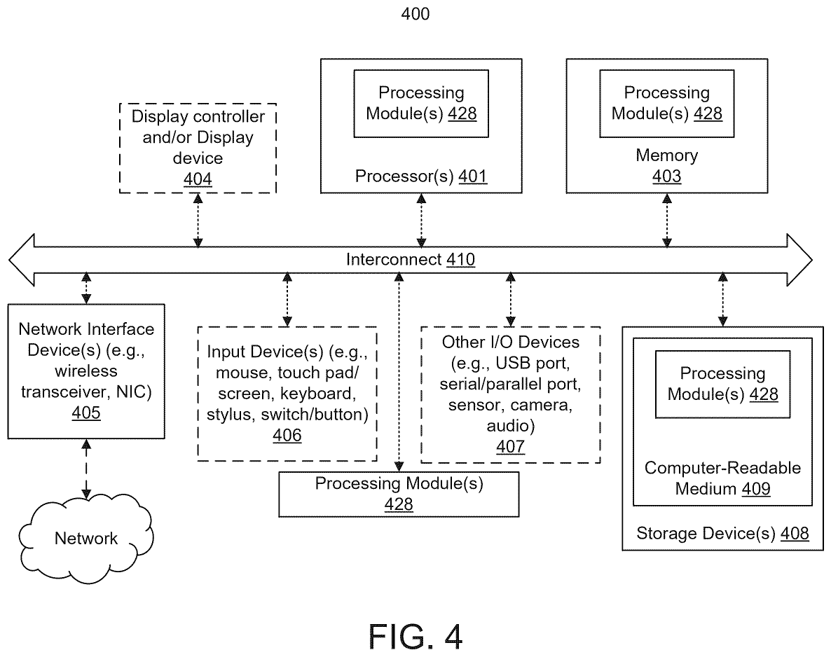

For additional details regarding computing devices, refer to FIG. 4 discussed further below.

Thus, as shown in FIG. 1A, a system in accordance with an embodiment may manage operation of a data processing system by thermally managing hardware resources of the data processing system in an attempt to mitigate the negative impacts that may be caused by, for example, heat generated as a byproduct of the data processing system tasked with the providing of the computer-implemented services.

While illustrated in FIG. 1A with a limited number of specific components, a system may include additional, fewer, and/or different components without departing from embodiments disclosed herein.

Turning to FIG. 1B, a second diagram illustrating a data processing system (e.g., 100) in accordance with an embodiment is shown. The data processing system shown in FIG. 1B may be a same data processing system as that shown and discussed with regard to FIG. 1A. However, in contrast to the side view of the data processing system shown in FIG. 1A, FIG. 1B may include a back-to-front and expanded viewpoint of data processing system 100, with a rear of chassis 112 being visible and facing out of the page.

As discussed with regard to FIG. 1A, chassis 112 may be implemented by an enclosure to house any number of hardware components of data processing system 100, the enclosure being, for example, a rack mount frame or a similarly capable housing structure (e.g., adapted to be mounted on, for example, vertical rack rails 111 and positioned vertically with respect to cooling module 113).

For example, and as previously discussed, a limited number of hardware components may be positioned in the limited cubic space provided within chassis 112's interior such as power components 104, management component 103, liquid cooling block 124, at least a part of fluid lines 126, and/or other components that may not be explicitly shown in either FIGS. 1A and/or 1B, not to be limited by embodiments discussed herein.

In FIG. 1A, an example assumption was suggested to discuss a scenario in which heat generated within chassis 112's interior may not be dissipated at a fast enough rate for thermal operating limits of the hardware components to be met sustainably. Therefore, cooling module 113 and its at least partially housed cooling components (“the second portion of cooling components”) were introduced to discuss the benefit(s) of such additional and separately housed cooling for data processing system 100.

However, for such cooling components as this second portion of cooling components to operate as would be necessary for effective implementation of this kind of distributed cooling (e.g., separately housed cooling), data processing system 100 may include hybrid power and data channel 140 to enable functionalities of the second portion of cooling components.

Such functionalities may require enablement by data processing system 100 in this way due to the separate cooling module (e.g., 113) being unable to (i) power itself and relying on the data processing system (e.g., 100) to power, at least, for example, fan 131 and pump 134, and (ii) set operating points of at least, for example, fan 131 and pump 134 and relies on the data processing system (e.g., 100) to set the operating points of the at least fan 131 and pump 134.

Therefore, to provide its functionality hybrid power and data channel 140 may include, for example, (i) power/data cable 128, (ii) cold line 136, (iii) hot line 138, (iv) break-out circuit card (e.g., 141 and/or 142), and/or (v) pass-through 137, each of which is discussed below.

Pass-through 137 may provide, for example, a gap in the enclosure that is chassis 112 that permits passage through the entirety of the enclosure's wall's thickness. This gap may be of a size large enough to permit passage of tubing and/or cabling components such as power/data cable 128, and/or cold line 136 and hot line 138 (e.g., fluid line 126, previously discussed). To provide its functionality, pass-through 137 may be implemented by a space/gap in a wall of the enclosure that is chassis 112 (e.g., in the rear wall of chassis 112).

The break-out circuit card may provide a means for operable connection between data processing system 100 and the tubing and/or cabling components that are to pass through pass-through 137 and lead to cooling module 113.

To provide its functionality, the break-out circuit card may be implemented by electronic component connection interfaces (positioned on a portion of circuit board) that provide points of connection that may be adapted to make physical contact with, for example, port slots of data processing system 100.

For additional details regarding break-out circuit cards, refer to FIGS. 1C and 1D discussed further below.

Power/data cable 128 may (i) supply power to components housed in cooling module 113, such as fan 131 and pump 134, from a power source of data processing system 100, such as power components 104, and/or (ii) enable transmissions of data between, and thereby facilitating communications between, management component 103 and the components housed in cooling module 113. To provide its functionality, power/data cable 128 may be implemented by, for example, the previously mentioned cabling, such cabling being manufactured for an intended purpose of directing/supplying/administering power to whatever components may operably connected to data processing system 100 via power/data cable 128, and/or transmitting data from management component 103 to the whatever components may operably connected.

Cold line 136 and hot line 138 may facilitate the flow path of the cooling liquid, cold line 136 directing cooled cooling liquid to liquid cooling block 124 from pump 134, and hot line 138 directing warmed cooling liquid to pump 134 from liquid cooling block 124.

To provide their functionalities, cold line 136 and hot line 138 may be implemented by, for example, the previously discussed fluid lines 126 as shown in FIG. 1A.

Thus, data processing system 100 may include hybrid power and data channel 140 integrated with a rear structural portion of chassis 112 to enable functionalities of the second portion of cooling components houses in cooling module 113 for data processing system 100.

While illustrated in FIG. 1B with a limited number of specific components, a system may include additional, fewer, and/or different components without departing from embodiments disclosed herein.

In the following discussions of FIGS. 1C and 1D, example diagrams of a hybrid power and data channel (e.g., 140) for facilitating operable connections with separately housed cooling components for a data processing system (e.g., 100) may be discussed. Within these discussions it will be appreciated that a hybrid power and data channel (e.g., 140) may include alternative component configurations/placements from one another. For example, the example shown in FIG. 1C may include a first component configuration for facilitating a directing of cooling liquid based on a shape/type/position of the previously mentioned break-out circuit card (e.g., 141 and 142), while FIG. 1D may include a second component configuration that may be less so (with regard to, e.g., the cooling liquid's flow path being based on the break-out circuit cards (e.g., 141 and 142).

Turning to FIG. 1C, a first diagram illustrating a hybrid power and data channel (e.g., 140) in accordance with an embodiment is shown.

As previously discussed, hybrid power and data channel 140 may enable facilitation of operable connections with separately housed cooling components for data processing system 100. To do so, and also as previously discussed, hybrid power and data channel 140 may include power/data cable 128, cold line 136, hot line 138, and/or pass-through 137, each of which is discussed above with regard to FIG. 1B.

Furthermore, hybrid power and data channel 140 may further include break-out circuit card 141. This break-out circuit card 141 may facilitate first operable connections between a peripheral component interface express (PCIe) slot (e.g., the one of the port slots) in the chassis and power/data cable 128 that may lead to the second portion of cooling components housed in the separate cooling module (e.g., 113). To facilitate such a first operable connection, break-out circuit card 141 may include, for example, two electronic component connection interfaces, each positioned, for example, on an opposite end of a circuit card to optimize cabling and tubing/fluid lines (e.g., 126) components that may pass through the previously discussed pass-through 137.

For example, a port-slot-side interface connection depicted on a right of break-out circuit card 141 (with respect to a left one) and may be adapted to connect to one of the limited number of previously discussed port slots available in chassis 112's interior.

For example, and as previously discussed, each of these port slots may provide a means for operable connection between data processing system 100 and a component that is placed such that a connection point/interface of the component may be in complete physical contact with one of the port slots.

A component-side interface connection may be depicted, for example, on a left of break-out circuit card 141 (with respect to a right one), and may be adapted to connect to, for example, power/data cable 128.

Additionally, break-out circuit card 141 may include a first type of pass-through 137 that accommodates the passage of both power/data cable 128 and fluid lines 126 (e.g., cold line 136 and hot line 138). Thus, by including the first type of pass-through 137, positioning of cabling and/or tubing components may be made to be more manageable.

Alternatively, hybrid power and data channel 140 may include cold line 136 and hot line 138 (e.g., fluid lines 126) having such placement that may not be based on the type of pass-through 137, discussed below with regard to FIG. 1D.

Turning to FIG. 1D, a second diagram illustrating a hybrid power and data channel (e.g., 140) in accordance with an embodiment is shown.

As previously discussed, hybrid power and data channel 140 may enable facilitation of operable connections with separately housed cooling components for data processing system 100. To do so, and also as previously discussed, hybrid power and data channel 140 may include power/data cable 128, cold line 136, hot line 138, and/or pass-through 137, each of which is discussed above with regard to FIG. 1C.

Furthermore, hybrid power and data channel 140 may further include break-out circuit card 142. This break-out circuit card 141 may *** facilitate second operable connections between a peripheral component interface express (PCIe) slot (e.g., the one of the port slots) in the chassis and power/data cable 128 that may lead to the second portion of cooling components housed in the separate cooling module (e.g., 113). To facilitate such a second operable connection, break-out circuit card 141 may include, for example, two electronic component connection interfaces, each positioned, for example, on an opposite end of a circuit card to optimize cabling components that may pass through the previously discussed pass-through 137.

For example, a port-slot-side interface connection depicted on a right of break-out circuit card 142 (with respect to a left one) and may be adapted to connect to one of the limited number of previously discussed port slots available in chassis 112's interior.

A component-side interface connection may be depicted, for example, on a left of break-out circuit card 142 (with respect to a right one), and may be adapted to connect to, for example, power/data cable 128.

Additionally, break-out circuit card 142 may include a second type of pass-through 137 that accommodates the passage of power/data cable 128, but not necessarily fluid lines 126 (e.g., cold line 136 and hot line 138). Thus, by including the second type of pass-through 137, positioning of cabling components may be made to be more manageable.

Thus, regardless of whether including break-out circuit card 141, break-out circuit card 142, and/or any other break-out circuit cards with alternative component configurations/placements, hybrid power and data channel 140 may enable functionalities of the second portion of cooling components houses in cooling module 113 for data processing system 100.

For additional information regarding thermal management of a data processing system (e.g., 100) and how during such thermal management (i) various components (previously discussed) may interact with one another and/or (ii) data may be used, refer to FIGS. 2-3 discussed further below.

While illustrated in FIGS. 1C-1D with a limited number of specific components, a system (e.g., a hybrid channel) may include additional, fewer, and/or different components without departing from embodiments disclosed herein.

To further clarify embodiments disclosed herein, an interaction diagram in accordance with an embodiment is shown in FIG. 2. The interaction diagram may illustrate how data may be obtained and used within the system (and/or components thereof) of FIGS. 1A-1D.

In the interaction diagram, processes performed by and interactions between components of a system in accordance with an embodiment are shown. In the diagram, components of the system are illustrated using a first set of shapes (e.g., 103, 144, 131, etc.), located towards a top of the page. Lines descend from these shapes. Processes performed by the components of the system are illustrated using a second set of shapes (e.g., 200, 204, etc.) superimposed over these lines. Interactions (e.g., communication, data transmissions, etc.) between the components of the system are illustrated using a third set of shapes (e.g., 206, 210, etc.) that extend between the lines. The third set of shapes may include lines terminating in one or two arrows. Lines terminating in a single arrow may indicate that one-way interactions (e.g., data transmission from a first component to a second component) occur, while lines terminating in two arrows may indicate that multi-way interactions (e.g., data transmission between two components) occur.

The processes and interactions are temporally ordered in an example order, with time increasing from the top of the page to a bottom of the page. For example, the process labeled as 202 may occur prior to the interaction labeled as 206. Additionally, for example, the interaction labelled 206 may occur during performance of the process labelled 204. It will be appreciated, however, that the processes and interactions may be performed in different orders, any may be omitted, and/or other processes or interactions may be performed without departing from embodiments disclosed herein.

Turning to FIG. 2, an interaction diagram in accordance with an embodiment is shown. This interaction diagram may illustrate processes and interactions that may occur during management of a data processing system's (e.g., 100's) operation with regard to, for example, (distributed) cooling of (e.g., thermal management of) the data processing system's hardware resources (e.g., any number of the data processing system's (hardware) components).

To thermally manage (e.g., cool) such hardware resources (e.g., 144) of data processing system 100, components of data processing system 100 (e.g., management component 103, hardware resources 144, and fan 121) and components of cooling module 113 operably connected to data processing system 100 (e.g., fan 131 and pump 134) may first collaboratively perform, for example, thermal management systems component identification process 200.

During thermal management systems component identification process 200, management component 103 may automatically take inventory of any and/or all functional components/devices operably connected to data processing system 100. To do so, management component 103 may, for example, automatically obtain electrical signals via each operable connection operably connecting a functional component/hardware resource of hardware resources 144 to data processing system 100 (and therefore, connecting any one of the cooling components to management component 103).

Such electrical signals may include, for example, data such as identifiers for (i) identifying a type of the component/hardware resource and/or (ii) identifying operation-defining configuration data allowing management component 103 to properly utilize a respective component/hardware resource for thermally managing hardware resources 144.

For example, management component 103 may identify, and obtain respective operation-defining configuration data for, hardware resources 144, fan 121, fan 131, and pump 134. In doing so, functional communication may be established using the operation-defining configuration data by management component 103.

Based on completion of thermal management systems component identification process 200, thermal management algorithm selection process 202 may be performed.

During thermal management algorithm selection process 202, management component 103 may, using the identifications of, and the operation-defining configuration data for, hardware resources 144, fan 121, fan 131, and pump 134 to select a thermal management algorithm from a set of thermal management algorithms that may be best suited to use with the identifications (e.g., any number of identified component/hardware resource). For example, such a selection between algorithms may be based on (i) the operation-defining configuration data, (ii) historical data regarding operation of the identified component(s)/hardware resource(s), and (ii) previously observed utilization of algorithms from the set of thermal management algorithms for previously facilitated thermal management of data processing system 100 (e.g., when the utilization happened, how the utilization happened, and/or what resulted from such utilization having happened).

Thus, by selecting the thermal management algorithm, operating points for cooling components may be obtained using the selected thermal management algorithm to then, in turn, manage operation of cooling components that may then allow the data processing system to facilitate optimal operation of hardware resources 144, as discussed below.

Based on completion of thermal management algorithm selection process 202, and the obtaining of the selected thermal management algorithm, thermal management process 204 may be performed using the selected thermal management algorithm to increase a likelihood of thermal operating limits being retained for hardware resources 144 of data processing system 100.

During thermal management process 204, management component 103 may (i) obtain information regarding thermal operating limits of hardware resources 144 whose retainment may be required should hardware resources 144 be used (and/or be queued for use) to facilitate data processing system 100's provisioning of computer implemented services as expected and/or desired by a consumer of such services, (ii) obtain data regarding operating conditions of hardware resources 144 that specify an active operating state (e.g., that may or may not be within respective thermal operating limits) of hardware resources 144 (e.g., specific/respective component temperatures, ongoing and/or queued workload performances by hardware resources 144, and/or other data specifying active operating states of hardware resources 144), (iii) obtain operating points for any number of cooling components based on the previously selected thermal management algorithm, the thermal operating limits, and/or the data specifying the active operating state(s), (iv) set the operating points for the any number of cooling components to change a cooling rate of hardware resources 144 such that at least the thermal operating limits of hardware resources 144 may be more likely retained, thereby being conducive for optimal operation of hardware resources 144, and thus, the providing of the computer implemented services by data processing system 100.

For example, during thermal management process 204, interactions 206-212 may be facilitated as discussed below.

At interaction 206, thermal data may be provided to management component 103 by hardware resources 144. This thermal data may include the above-mentioned data specifying the active operating state and/or the thermal operating limits associated with hardware resources 144.

The thermal data may be provided, for example, (i) by hardware resources 144 automatically providing the thermal data to management component 103, for example, in set time intervals, (ii) by management component 103 requesting the thermal data from hardware resources 144 and hardware resources 144 fulfilling such requests, (iii) by obtaining, by management component 103, the thermal data from storage (e.g., the thermal data having been placed in storage by, for example, hardware resources 144 to obtain/maintain a record of hardware resources 144's past and ongoing operation), and/or (iv) any other processes not to be limited by embodiments discussed herein. Management component 103 may therefore obtain operating points for various cooling components by using the (thermal) data specifying the active operating state and the thermal operating limits as input for the selected thermal management algorithm to obtain (new) operating points as output from the selected thermal management algorithm. For example, assume a first (new) operating point is obtained for fan 121 (e.g., housed in chassis 112 and from the previously discussed first portion of cooling components), a second (new) operating point is obtained for fan 131 (e.g., included in cooling module 113 and from the previously discussed second portion of cooling components), and a third (new) operating point is obtained for pump 134 (e.g., also included in cooling module 113 and also from the previously discussed second portion of cooling components).

Therefore, (i) at interaction 208, the first (new) operating point may be set for fan 121, (ii) at interaction 210, the second (new) operating point may be set for fan 131, and (iii) at interaction 212, the third (new) operating point may be set for pump 134. These operating points may be set by, for example, management component 103 providing commands and/or otherwise instructing fan 121, fan 131, and pump 134, to change their operations, respectively, based on the obtained (new) operating points to change the rate of cooling for hardware resources 144 (e.g., each cooling component changing its respective contribution to the rate of cooling).

For example, assuming that the first, the second, and the third (new) operating points are respectively different from (previous) operating points that were set prior for the cooling components, then the contributions to the rate of cooling may have changed. However, it will be appreciated that while such contributions may change, there may be cases that result in the rate of cooling changing, and there may be cases that result in no change to the rate of cooling.

Additionally, it will be appreciated that although discussed with regard to setting just three operating points, management component 103 may set any number of operating points for any number of cooling components (e.g., and/or components otherwise regarded as hardware components) based on the identified cooling components resulting from thermal management systems component identification process 200, the thermal algorithm selected based on performance of thermal management algorithm selection process 202, and/or the thermal data obtained from hardware resources 144.

Thus, using processes and interactions shown in FIG. 2, a management component (e.g., being an out-of-band component of a data processing system (e.g., 100)) may thermally manage hardware resources (e.g., 144) of the data processing system. By doing so, a likelihood of thermal operating limits being retained for each of hardware resources 144 may be increased, thereby increasing the likelihood of the data processing system providing the computer-implemented services as expected and/or desired by a consumer of said services.

Any of the processes illustrated using the second set of shapes and/or interactions illustrated using the third set of shapes may be performed, in part or whole, by digital processors (e.g., central processors, processor cores, etc.) that execute corresponding instructions (e.g., computer code/software). Execution of the instructions may cause the digital processors to initiate performance of the processes. Any portions of the processes may be performed by the digital processors and/or other devices. For example, executing the instructions may cause the digital processors to perform actions that directly contribute to performance of the processes, and/or indirectly contribute to performance of the processes by causing (e.g., initiating) other hardware components to perform actions that directly contribute to the performance of the processes.

Any of the processes illustrated using the second set of shapes and interactions illustrated using the third set of shapes may be performed, in part or whole, by special purpose hardware components such as digital signal processors, application specific integrated circuits, programmable gate arrays, graphics processing units, data processing units, and/or other types of hardware components. These special purpose hardware components may include circuitry and/or semiconductor devices adapted to perform the processes. For example, any of the special purpose hardware components may be implemented using complementary metal-oxide semiconductor-based devices (e.g., computer chips).

Any of the processes and interactions may be implemented using any type and number of data structures. The data structures may be implemented using, for example, tables, lists, linked lists, unstructured data, data bases, and/or other types of data structures. Additionally, while described as including particular information, it will be appreciated that any of the data structures may include additional, less, and/or different information from that described above. The informational content of any of the data structures may be divided across any number of data structures, may be integrated with other types of information, and/or may be stored in any location.

As discussed above, the components of FIGS. 1A-1C may perform various methods/processes to manage operation of a data processing system (e.g., 100). FIG. 3 illustrates a method that may be performed by the components of the (distributed) system previously discussed with regard to FIGS. 1A-1C. In the diagram discussed below and shown in FIG. 3, any of the operations may be repeated, performed in different orders, and/or performed in parallel with, or in a partially overlapping in time manner with, other operations.

Turning to FIG. 3, a flow diagram illustrating a method of managing operation of a data processing system in accordance with an embodiment is shown. The method may be performed, for example, by any of the components of the systems shown in FIGS. 1A-1D (e.g., management component 103).

For the following discussions of operations performed to implement this method, it will be appreciated that the data processing system is assumed to be mounted with, for example, a rack mount chassis system as shown and discussed with regard to FIG. 1A. This, for example, may mean that an enclosure (e.g., a first enclosure)/chassis (e.g., 112) of the data processing system is positioned vertically with respect to an enclosure (e.g., a second enclosure)/separate cooling module (e.g., 133), and that this first enclosure and this second enclosure may be vertically positioned with respect to one another due to being fixed to a rack of the rack system. For example, the rack may include vertical rack rails 111 as shown in FIG. 1A. The first and second enclosures were fixed to these rails.

At operation 300, a first portion of cooling components that are in a chassis of the data processing system and a second portion of cooling components that are positioned in a separate cooling module and operably connected to a management component of the data processing system are identified by the management component.

The first portion and the second portion may be identified by performing a type of component identification process as previously discussed (e.g., in FIG. 2, with respect to process 200). Such a component identification process may include, for example, taking inventory of all operably connected hardware components/devices of the data processing system. For example, by taking this inventory, each operable connection to the management component may provide/return at least one identifier to the management component until a number of identifiers may be obtained.

Each of these identifiers may then be used to obtain respectively associated configuration settings (e.g., the previously discussed operation-defining configuration data) for configuring corresponding operable connections based on respectively provided/returned identifiers. In doing so, an independent communication channel may be established for each operable connection operably connected to the management component, the communication being possible due to the management component knowing what type of component each communication channel is established for based on the associated identifier (and therefore using associated operation-defining configuration data).

For example, each of these obtained identifiers may be used to correctly identify a type of each of the operably connected hardware components/devices by using the identifiers in a lookup process.

For example, first identifiers may be obtained and used in such a lookup process in a knowledge base, resulting in the first identifiers being associated with, and therefore used to correctly identify, the first portion of cooling components (e.g., housed in chassis 112). Similarly, second identifiers may be used to correctly identify the second portion of cooling components (e.g., housed in the enclosure of cooling module 113) and (although not explicitly mentioned in the first description of operation 300) third identifiers may be used to correctly identify hardware resources of the data processing system that are housed in the chassis (e.g., along with the first portion of cooling components) and are also operably connected to the management component.

Using these identifiers in the lookup process as part of this identification may therefore also, for example, return respectively associated configuration settings (e.g., the operation-defining configuration data for configuring respectively corresponding operable connections) from the knowledge base. This knowledge base may simply be, for example, a repository of known components and all relevant structural, functional, and/or otherwise useable information associated with each of the components. Thus, in addition to the identification of the first portion and the second portion, the hardware resources may also be identified.

Such an identification may occur and/or be initiated, for example, automatically based on the management component being powered, as well as each operably connected hardware component/device receiving power (e.g., this identification may occur based on the data processing system being powered on). For example, assume that the second portion of the cooling components includes (i) a fan, (ii) a pump to pump a cooling liquid, and (iii) a thermal dissipator to cool the cooling liquid using an airflow generated by the fan. Further assume that the separate cooling module (and therefore, each component of the second portion of cooling components) is unable to power itself, and thus relies on the data processing system to power, at least, the fan and the pump.

Additionally, it will be appreciated that the management component may be a management controller hosted by the data processing system. However, this management controller may operate independently from the hardware resources (e.g., independently from all other hardware components of the data processing system), the management controller being tasked with managing operation of the hardware resources while the hardware resources cause the data processing system to provide desired computer implemented services.

Now imagine a scenario in which the data processing system is powered on. Based on the second portion of cooling components relying on the same power source as that of the first portion and the hardware resources (and the management component also being powered by this power source of the data processing system), all the operable connections may activate by transmitting electrical signals automatically from the operably connected hardware components/devices to the management component. These electrical signals may not only be used to identify the presence of those components operably connected but may also be used to obtain the previously-discussed identifiers.

Although discussed within the example context of a single chassis of the data processing system and a single separate cooling module, it will be appreciated that the second portion of the cooling components may provide cooling for at least one of the hardware resources and at least one other hardware resource positioned in a second data processing system's chassis. For example, the data processing system and the separate cooling module may be positioned in a rack with this second data processing system (e.g., a chassis of the second data processing system). Furthermore, it will be appreciated that any number of separate cooling modules may be used similarly and in collaboration with such rack systems as mentioned above.

At operation 302, a thermal management algorithm for thermally managing hardware resources of the data processing system using the first portion of the cooling components and the second portion of the cooling components is selected by the management component.

The thermal management algorithm may be selected by (i) obtaining a set of thermal management algorithms (e.g., from storage), each algorithm being associated with a respective system configuration (e.g., each system configuration defining a type and/or quantity of each hardware component operably connected to said system) in a database, (ii) obtaining an active configuration of the data processing system based on the identified components (e.g., the active configuration may include a list of the operably connected first portion of cooling components, second portion of cooling components, and hardware resources), (iii) matching the active configuration to one of the system configurations from the database to obtain a matching system configuration, and (iv) selecting one of the thermal management algorithms from the set that is associated with the matching system configuration.

The associations between each algorithm from the set and a corresponding system configuration may be based on what thermal management algorithm is likely to be best suited to use with what combination of operably connected hardware components for a data processing system. For example, such association may be based on (i) the operation-defining configuration data defining how any given component may handle transmissions of data, (ii) historical data regarding previously observed functionality of the operably connected hardware components, and/or (ii) previously observed utilization of algorithms from the set during previously facilitated thermal management of the data processing system (e.g., when the utilization happened, how the utilization happened, and/or what resulted from such utilization having happened).

Once selected, the selected thermal management algorithm may be used as an algorithm to determine what, if any, new operating points should be set (e.g., set for any and/or all cooling components of the data processing system) in order to retain thermal operating limits of, for example, the hardware resources. For example, the selected thermal management algorithm may be a cultivated algorithm that takes into account all active operating conditions, configurations, capabilities, and/or functional shortcomings of the data processing system to determine how best to manage cooling components such that the thermal operating limits of any and/or all the hardware components of the data processing system are most efficiently retained.

At operation 304, first operating points for the first portion and second operating points for the second portion are selected by the management component and using the thermal management algorithm and at least a temperature of one of the hardware resources.

The first operating points and the second operating points may be selected by (i) obtaining at least the temperature of the one of the hardware resources and/or any other thermal data from any portion of the hardware resources (e.g., temperatures of other hardware components, inferred future temperatures of the hardware components, current and/or previous operating point of any portion of the cooling components, etc.), (ii) using at least the temperature and/or the any other thermal data as input for the selected thermal management algorithm, and (iii) obtaining, based on the input, output from the selected thermal management algorithm that may include the first, and the second, operating points.

By incorporating thermal data such as the temperature of the one of the hardware resources, the selected thermal management algorithm may output the above-mentioned operating points, that if set, are likely to retain the thermal operation limits of, for example, at least the one of the hardware resources.

It will be appreciated however, due to the separate cooling module lacking its own (e.g., dedicated) power source or management components, that along with the separate cooling module relying on the data processing system to power the second portion of cooling components, the separate cooling module may further rely of the data processing system to set the second operating points of the second portion of cooling components (e.g., operating points of at least the fan and the pump).

At operation 306, the second operating points for the second portion are set by the management component using a hybrid power and data channel between the management component and the second portion of the cooling components to modify a cooling rate for at least the one of the hardware resources to retain the one of the hardware resources within thermal operating limits.

The second operating points may be set for the second portion by (i) associating an operating point of the second operating points with an intended component from the second portion of cooling components, and doing so for each of the second operating points, (ii) respectively obtaining executable instructions (e.g., instructions capable of being properly executed when obtained by an intended recipient of such instructions) for setting each operating point for its intended recipient with which such an operating point may be now associated, (iii) further associating each operating point with an operable connection configured for properly transmitting data to each respectively intended recipient, and (iv) using such associations of an operating point from the second operating points to transmit, via an associated operable connection, the operating point to its intended recipient component along with associated executable instructions to be executed by the intended recipient component.

For example, as previously discussed with regard to how the separate cooling module may be powered and/or had its operating points set by the data processing system, the data processing system may include the hybrid power and data channel (e.g., 140 in FIGS. 1A-1D) to operably connect the management component to each component of the second portion of cooling components housed in the separate cooling module's enclosure.

For example, as previously discussed, the hybrid power and data channel may include (i) a break-out circuit card positioned with a (ii) pass-through at a first end of the chassis, a (iii) connection between the break-out circuit card and the management component and/or a main circuit board; and a (iv) hybrid power/data cable to interconnect the break-out circuit card with the second portion of the cooling components. The break-out circuit card may, for example, be adapted to be positioned in a peripheral component interface express (PCIe) slot in the chassis. The pass-through may include, for example, openings for a pair of fluid lines to pass through to establish a cooling loop from the one of (and/or any of) the hardware resources to the second portion of the cooling components. The connection may be adapted to, for example, retrieve power from the main circuit board, and the break-out circuit card may be further adapted to, for example, direct the power to the second portion of the cooling components via the hybrid power/data cable.

For additional information regarding each of these and/or the hybrid power and data channel as a whole, refer to the figure descriptions discussed previously with regard to FIGS. 1A-2 further above.

Thus, the second operating points may be set for the second portion of cooling components.

Additionally, although not explicitly stated in the description of operation 306, the first operating points may be similarly set (the setting of the first operating points being similar to the setting of the second operating points) for the first portion of cooling components, however, without the required utilization of the hybrid power and data channel. Such reliance on the hybrid power and data channel may be (at least in part) due to the first portion of cooling components relying on operable connections already housed by the chassis (e.g., 112) of the data processing system (e.g., such operable connections being implemented as discussed with regard to electronics 101 shown in FIG. 1A).

For additional details regarding, for example, how the first portion of cooling components and/or the second portion of cooling components may function and/or be positioned (e.g., with regard to one another, with regard to being mounted on a rack mount chassis system, and/or with regard to any number of other contexts not to be limited by embodiments discussed herein), refer to the previous discussions of FIGS. 1A-2 further above.

The method may end following operation 306.

Thus, a method of managing operation of a data processing system in accordance with an embodiment is shown.

Any of the processes and/or components illustrated in and/or discussed with regard to FIGS. 1A-3 may be implemented with and/or used in conjunction with one or more computing devices.

Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 400 is intended to show a high-level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very-long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401, which may be a low power multi-core processor socket such as an ultra-low voltage processor, may act as a main processing unit and central hub for communication with the various components of the system. Such processor can be implemented as a system on chip (SoC). Processor 401 is configured to execute instructions for performing the operations discussed herein. System 400 may further include a graphics interface that communicates with optional graphics subsystem 404, which may include a display controller, a graphics processor, and/or a display device.

Processor 401 may communicate with memory 403, which in one embodiment can be implemented via multiple memory devices to provide for a given amount of system memory. Memory 403 may include one or more volatile storage (or memory) devices such as random-access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as an embedded controller (not shown) may control a keyboard or thermal sensor, dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components as such details are not germane to embodiments disclosed herein. It will also be appreciated that network computers, handheld computers, mobile phones, servers, and/or other data processing systems which have fewer components, or (perhaps) more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and (generally) conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A method for thermally managing a data processing system, the method comprising:
identifying, by a management component of the data processing system, a first portion of cooling components that are in a chassis of the data processing system and a second portion of cooling components that are positioned in a separate cooling module and operably connected to the management component;
selecting, by the management component, a thermal management algorithm for thermally managing hardware resources of the data processing system using the first portion of the cooling components and the second portion of the cooling components;
selecting, by the management component and using the thermal management algorithm and at least a temperature of one of the hardware resources, first operating points for the first portion and second operating points for the second portion; and
setting, by the management component, the second operating points for the second portion using a hybrid power and data channel between the management component and the second portion of the cooling components to modify a cooling rate for at least the one of the hardware resources to retain the one of the hardware resources within thermal operating limits.

2. The method of claim 1, wherein the hybrid power and data channel comprises:
a break-out circuit card positioned with a pass-through at a first end of the chassis;
a connection between the break-out circuit card and the management component and/or a main circuit board; and
a hybrid power/data cable to interconnect the break-out circuit card with the second portion of the cooling components.

3. The method of claim 2, wherein the connection is adapted to retrieve power from the main circuit board, and the break-out circuit card is adapted to direct the power to the second portion of the cooling components via the hybrid power/data cable.

4. The method of claim 2, wherein the break-out circuit card is adapted to be positioned in a peripheral component interface express (PCIe) slot in the chassis.

5. The method of claim 2, wherein the pass-through comprises openings for a pair of fluid lines to pass through to establish a cooling loop from the one of the hardware resources to the second portion of the cooling components.

6. The method of claim 1, wherein the second portion of the cooling components comprise:
a fan;
a pump to pump a cooling liquid; and
a thermal dissipator to cool the cooling liquid using an airflow generated by the fan.

7. The method of claim 6, wherein the separate cooling module is unable to power itself and relies on the data processing system to power, at least, the fan and the pump.

8. The method of claim 7, wherein the separate cooling module is unable to set operating points of at least the fan and the pump and relies on the data processing system to set the operating points of the at least the fan and the pump.

9. The method of claim 1, wherein the second portion of the cooling components are adapted to provide cooling for the one of the hardware resources and at least one other hardware resource positioned in a second data processing system; and the data processing system, the separate cooling module, and the second data processing system being positioned in a rack.

10. The method of claim 1, wherein the management component is a management controller that is hosted by the data processing system, but that operates independently from the hardware resources, the management controller being tasked with managing operation of the hardware resources while the hardware resources provide desired computer implemented services.

11. A non-transitory machine-readable medium having instructions stored therein, which when executed by a processor, cause the processor to perform operations for thermally managing a data processing system, the operations comprising:
identifying, by a management component of the data processing system, a first portion of cooling components that are in a chassis of the data processing system and a second portion of cooling components that are positioned in a separate cooling module and operably connected to the management component;
selecting, by the management component, a thermal management algorithm for thermally managing hardware resources of the data processing system using the first portion of the cooling components and the second portion of the cooling components;
selecting, by the management component and using the thermal management algorithm and at least a temperature of one of the hardware resources, first operating points for the first portion and second operating points for the second portion; and
setting, by the management component, the second operating points for the second portion using a hybrid power and data channel between the management component and the second portion of the cooling components to modify a cooling rate for at least the one of the hardware resources to retain the one of the hardware resources within thermal operating limits.

12. The non-transitory machine-readable medium of claim 11, wherein the hybrid power and data channel comprises:
a break-out circuit card positioned with a pass-through at a first end of the chassis;
a connection between the break-out circuit card and the management component and/or a main circuit board; and
a hybrid power/data cable to interconnect the break-out circuit card with the second portion of the cooling components.

13. The non-transitory machine-readable medium of claim 12, wherein the connection is adapted to retrieve power from the main circuit board, and the break-out circuit card is adapted to direct the power to the second portion of the cooling components via the hybrid power/data cable.

14. The non-transitory machine-readable medium of claim 12, wherein the break-out circuit card is adapted to be positioned in a peripheral component interface express (PCIe) slot in the chassis.

15. The non-transitory machine-readable medium of claim 12, wherein the pass-through comprises openings for a pair of fluid lines to pass through to establish a cooling loop from the one of the hardware resources to the second portion of the cooling components.

16. A system, comprising:
a processor; and
a memory coupled to the processor to store instructions, which when executed by the processor, cause operations for thermally managing a data processing system, the operations comprising:
identifying, by a management component of the data processing system, a first portion of cooling components that are in a chassis of the data processing system and a second portion of cooling components that are positioned in a separate cooling module and operably connected to the management component;
selecting, by the management component, a thermal management algorithm for thermally managing hardware resources of the data processing system using the first portion of the cooling components and the second portion of the cooling components;
selecting, by the management component and using the thermal management algorithm and at least a temperature of one of the hardware resources, first operating points for the first portion and second operating points for the second portion; and
setting, by the management component, the second operating points for the second portion using a hybrid power and data channel between the management component and the second portion of the cooling components to modify a cooling rate for at least the one of the hardware resources to retain the one of the hardware resources within thermal operating limits.

17. The system of claim 16, wherein the hybrid power and data channel comprises:
a break-out circuit card positioned with a pass-through at a first end of the chassis;
a connection between the break-out circuit card and the management component and/or a main circuit board; and
a hybrid power/data cable to interconnect the break-out circuit card with the second portion of the cooling components.

18. The system of claim 17, wherein the connection is adapted to retrieve power from the main circuit board, and the break-out circuit card is adapted to direct the power to the second portion of the cooling components via the hybrid power/data cable.

19. The system of claim 17, wherein the break-out circuit card is adapted to be positioned in a peripheral component interface express (PCIe) slot in the chassis.

20. The system of claim 17, wherein the pass-through comprises openings for a pair of fluid lines to pass through to establish a cooling loop from the one of the hardware resources to the second portion of the cooling components.
